(19) United States
(12) Patent Application Publication
(10) Pub. No.: US 2017/0047337 A1
(43) Pub. Date: Feb. 16, 2017

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventor: Hideto TAKEKIDA, Nagoya (JP)

(73) Assignee: Kabushiki Kaisha Toshiba, Minato-ku (JP)

(21) Appl. No.: 15/067,892

(22) Filed: Mar. 11, 2016

Related U.S. Application Data
(60) Provisional application No. 62/204,103, filed on Aug. 12, 2015.

(51) Int. Cl. H01L 27/115; H01L 23/535; G11C 16/04

(52) U.S. Cl. CPC H01L 27/11524; G11C 16/0483; H01L 23/535

(57) ABSTRACT

A nonvolatile semiconductor memory device according to an embodiment comprises: a silicon substrate; and a plurality of memory cells that nonvolatilely accumulate a charge as data, disposed along at least a first direction, on the substrate. A diffusion layer is disposed continuously in a surface of the substrate of a region straddling the plurality of memory cells disposed along the first direction. The memory cell incudes an epitaxial silicon layer disposed on the diffusion layer.

### CROSS REFERENCE TO RELATED APPLICATION

This application is based upon and claims the benefit of priority from U.S. Provisional Patent Application No. 62/204,103, filed on Aug. 12, 2015, the entire contents of which are incorporated herein by reference.

### FIELD

Embodiments described herein relate generally to a nonvolatile semiconductor memory device and a method of manufacturing the same.

### BACKGROUND

In the field of nonvolatile semiconductor memory devices having memory cells disposed two-dimensionally on a substrate, such as NAND type flash memories, cell characteristics must be maintained in a good and constant state.

### BRIEF DESCRIPTION OF THE DRAWINGS

FIG. 1 shows an example of a circuit diagram showing a schematic configuration of a memory block included in a semiconductor memory device according to an embodiment.

FIG. 2 is a plan view showing an example of schematic configuration of a memory cell array of a nonvolatile semiconductor memory device according to an embodiment.

FIG. 3 is a partial plan view showing an example of configuration of the nonvolatile semiconductor memory device according to the embodiment.

FIG. 4 is a partial plan view showing an example of configuration of the nonvolatile semiconductor memory device according to the embodiment.

FIG. 5 is a partial plan view showing an example of configuration of the nonvolatile semiconductor memory device according to the embodiment.

FIG. 6 is a partial plan view showing an example of configuration of the nonvolatile semiconductor memory device according to the embodiment.

FIG. 7 is a partial plan view showing an example of configuration of the nonvolatile semiconductor memory device according to the embodiment.

FIG. 8 is a partial plan view showing an example of configuration of the nonvolatile semiconductor memory device according to the embodiment.

FIG. 9 is a partial cross-sectional view showing an example of configuration of a nonvolatile semiconductor memory device of a first embodiment.

FIG. 10 is a process drawing showing a method of manufacturing the nonvolatile semiconductor memory device of the first embodiment.

FIG. 11 is a process drawing showing the method of manufacturing the nonvolatile semiconductor memory device of the first embodiment.

FIG. 12 is a process drawing showing the method of manufacturing the nonvolatile semiconductor memory device of the first embodiment.

FIG. 13 is a process drawing showing the method of manufacturing the nonvolatile semiconductor memory device of the first embodiment.

FIG. 14 is a process drawing showing the method of manufacturing the nonvolatile semiconductor memory device of the first embodiment.

FIG. 15 is a process drawing showing the method of manufacturing the nonvolatile semiconductor memory device of the first embodiment.

FIG. 16 is a process drawing showing the method of manufacturing the nonvolatile semiconductor memory device of the first embodiment.

FIG. 17 is a process drawing showing the method of manufacturing the nonvolatile semiconductor memory device of the first embodiment.

FIG. 18 is a process drawing showing the method of manufacturing the nonvolatile semiconductor memory device of the first embodiment.

FIG. 19 is a process drawing showing the method of manufacturing the nonvolatile semiconductor memory device of the first embodiment.

FIG. 20 is a process drawing showing the method of manufacturing the nonvolatile semiconductor memory device of the first embodiment.

FIG. 21 is a partial cross-sectional view showing an example of configuration of a nonvolatile semiconductor memory device of a second embodiment.

FIG. 22 is a process drawing showing a method of manufacturing the nonvolatile semiconductor memory device of the second embodiment.

FIG. 23 is a partial cross-sectional view showing an example of configuration of a nonvolatile semiconductor memory device according to a comparative example.

FIG. 24 is a partial cross-sectional view showing an example of configuration of a nonvolatile semiconductor memory device according to another comparative example.

### DETAILED DESCRIPTION

A nonvolatile semiconductor memory device according to an embodiment described below comprises: a silicon substrate; and a plurality of memory cells that nonvolatilely accumulate a charge as data, disposed along at least a first direction, on the substrate. A diffusion layer is disposed continuously in a surface of the substrate of a region straddling the plurality of memory cells disposed along the first direction. The memory cell incudes an epitaxial silicon layer disposed on the diffusion layer.

Next, nonvolatile semiconductor memory devices according to embodiments will be described in detail with reference to the drawings. Note that these embodiments are merely examples. Moreover, each of the drawings of the nonvolatile semiconductor memory devices employed in the embodiments below is schematic, and thicknesses, widths, ratios, and so on, of layers are not limited to those described in the drawings.

The nonvolatile semiconductor memory devices of the embodiments below have a fringe cell structure in which a diffusion layer is formed continuously in a region where a memory cell unit is disposed. Moreover, in the nonvolatile semiconductor memory devices below, a memory cell having a so-called flat cell structure is described as an example. However, this is merely an example, and technology of these embodiments may be applied also to a so-called rocket cell structure.

### First Embodiment

### Configuration of Nonvolatile Semiconductor Memory Device According to First Embodiment

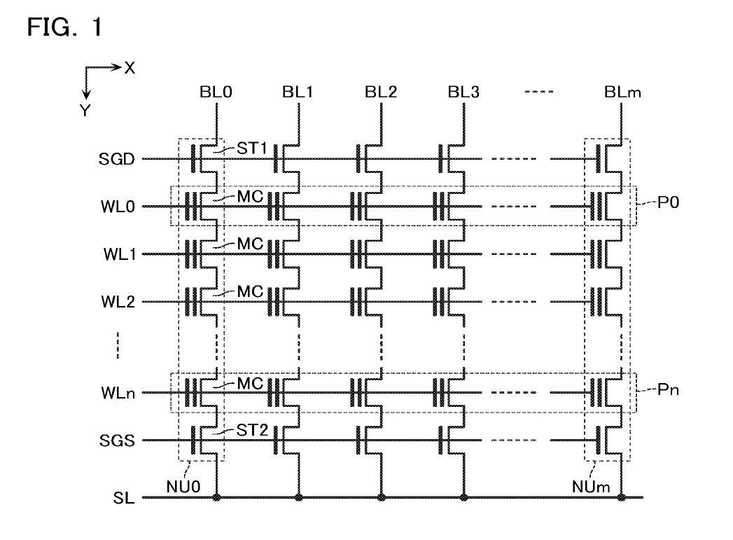

FIG. 1 is an example of a circuit diagram showing a schematic configuration of one memory block included in a NAND type flash memory according to a first embodiment. The memory block of the flash memory comprises (m+1) NAND cell units (NU0 to NUm) disposed sequentially along an X direction (m is a natural number). Each NAND cell unit comprises: select transistors ST1 and ST2; and (n+1) memory cell transistors MT (n is a natural number). The drain side select transistors ST1 respectively included in the (m+1) NAND cell units have their respective drains connected to bit lines BL0 to BLm, and each have their control gate electrodes commonly connected to a select gate line SGD. The source side select transistors ST2 each have their sources commonly connected to a source line SL, and each have their control gate electrodes commonly connected to a select gate line SGS.

In each NAND cell unit, the (n+1) memory cell transistors MT are disposed so as to be connected in series between a source of the drain side select transistor ST1 and a drain of the source side select transistor ST2.

Word lines WL0 to WLn commonly connect control gate electrodes of the memory cell transistors MT, among the NAND cell units in one memory block. In other words, the control gate electrodes of the memory cell transistors MT (disposed along the X direction) in an identical row in one memory block are connected to an identical word line WL. The (m+1) memory cell transistors MT connected to this identical word line WL are treated as one page, and write of data and read of data are performed on the basis of this page. As a result, the embodiments include from a page P0 to a page Pn.

Moreover, the bit lines BL0 to BLm commonly connect the drains of the drain side select transistors ST1, among the memory blocks. In other words, the memory cell transistors MT of the NAND cell units (disposed along a Y direction) in an identical column over a plurality of the memory blocks are connected to an identical bit line BL.

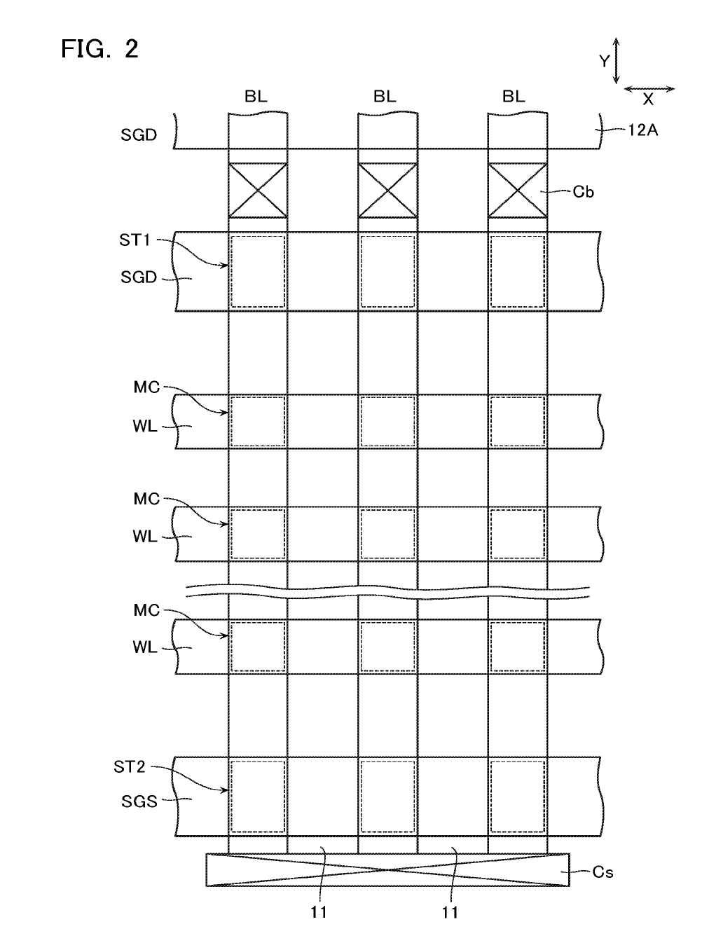

FIG. 2 shows an example of schematic configuration of a memory cell array of a nonvolatile semiconductor memory device according to an embodiment.

In the nonvolatile semiconductor memory device according to the embodiment, word lines WL and bit lines BL are arranged intersecting each other, and a memory cell MC is formed at each of intersections of those word lines WL and bit lines BL. In other words, a plurality of the memory cells MC are disposed along an X direction in which the word lines WL extend and a Y direction in which the bit lines BL extend that intersects this X direction.

A plurality of the memory cells MC disposed along the Y direction are connected in series by a diffusion layer DL not illustrated in this FIG. 2. The plurality of memory cells MC connected in series configure one memory string (NAND cell unit). One end of the memory string is connected to the bit line BL via a drain side select gate transistor ST1.

In addition, the other end of the memory string is connected to an unillustrated source line SL via a source side select gate transistor ST2. The source line SL and the source side select gate transistor ST2 are connected via a source side contact Cs.

A gate of the drain side select gate transistor ST1 is connected to a drain side select gate line SGD arranged parallel to the word line WL. Moreover, a gate of the source side select gate transistor ST2 is connected to a source side select gate line SGS arranged parallel to the word line WL.

Moreover, an element isolation insulating film 11 that extends having the Y direction as its longitudinal direction is formed with a certain spacing in the X direction on a surface of a substrate where the memory cell MC is disposed. The element isolation insulating film is formed from, for example, silicon oxide (SiO₂). A region of the substrate sandwiched by the element isolation insulating films 11 is an active area AA where the memory string (memory cell) is formed. That is, the surface of the substrate is electrically isolated into a plurality of the active areas AA by the element isolation insulating film 11. The active areas AA, similarly to the element isolation insulating films 11, extend having the Y direction as their longitudinal direction and are formed with a certain spacing in the X direction.

In addition, although illustration thereof is omitted, a peripheral region of the memory cell array shown in FIG. 2 has disposed therein a contact for achieving electrical connection with a peripheral transistor or a peripheral circuit, and various kinds of wiring lines.

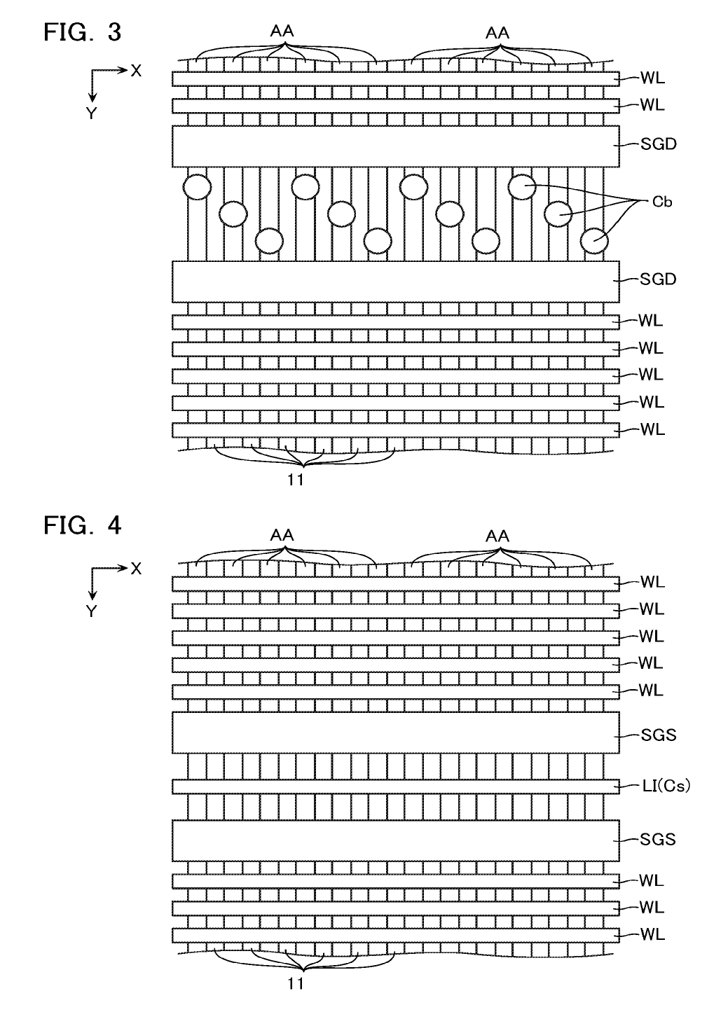

FIGS. 3 to 8 are plan views showing examples of arrangement of wiring lines in each of wiring line layers.

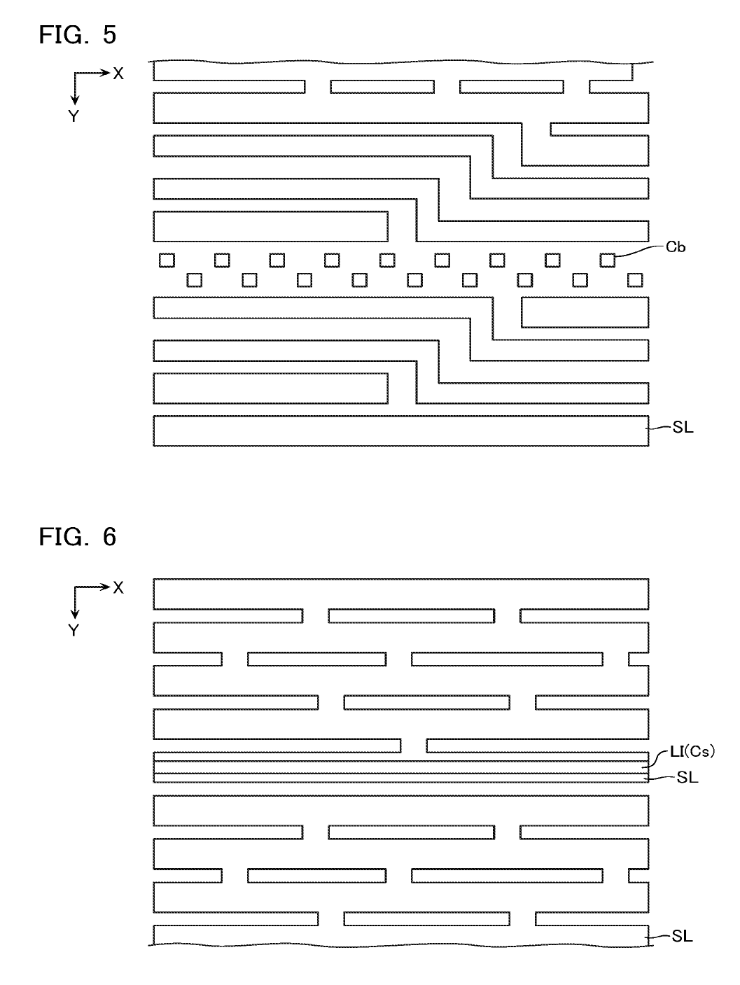

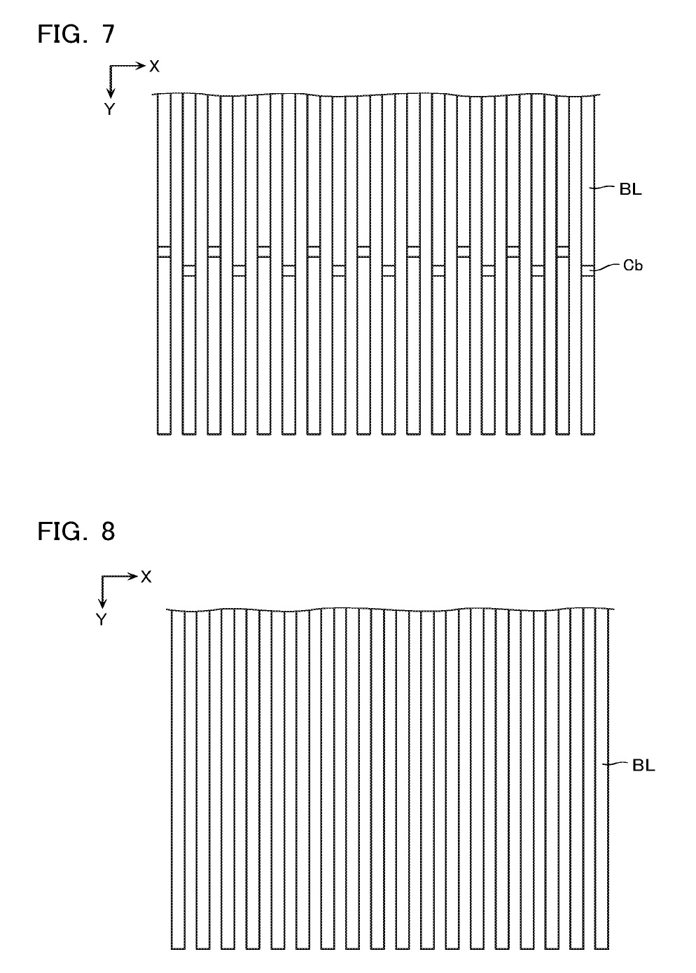

FIGS. 3 and 4 show a layer where the word line WL is disposed; FIGS. 5 and 6 show a layer where the source line SL is disposed, which is a higher layer than the layer where the word line WL is disposed; and FIGS. 7 and 8 show a layer where the bit line BL is disposed, which is a higher layer than the layer where the source line SL is disposed. Moreover, FIGS. 3, 5, and 7 show a region including a portion where a drain side contact Cb is disposed; and FIGS. 4, 6, and 8 show a region including a portion where the source side contact Cs is disposed.

As shown in FIGS. 3 and 4, the word lines WL each extend in the X direction and are arranged in parallel in the Y direction. Moreover, disposed adjacently to the word line WL disposed most at an end is the drain side select gate line SGD or source side select gate line SGS. A columnar bit line contact Cb is disposed in each active area AA isolated by the element isolation insulating film 11, in a region sandwiched by two adjacent drain side select gate lines SGD. The plate-like source side contact Cs is disposed in a region sandwiched by two adjacent source side select gate lines SGS.

As shown in FIGS. 5 and 6, the mesh-shaped source line SL is disposed in a higher layer than the layer where the word line WL, and so on, are disposed shown in FIGS. 3 and 4. On a source side of each NAND cell unit, 0 V is applied collectively during read, hence there is no need to make contact to each NAND cell unit. Therefore, as shown in FIGS. 5 and 6, the source line SL corresponding to each NAND cell unit is disposed undivided. Moreover, configuring the source line SL in a mesh shape makes it possible for a function as a barrier layer to a leak current from an upper layer structure to also be achieved.

As shown in FIGS. 7 and 8, the bit lines BL are configured by a metal layer having an identical width to the diffusion layer, and are arranged in parallel in the X direction extending in the Y direction. Moreover, the bit side contact Cb is connected to each bit line BL. This is because it is required to make contact to each NAND cell unit on a drain side of the NAND cell unit.

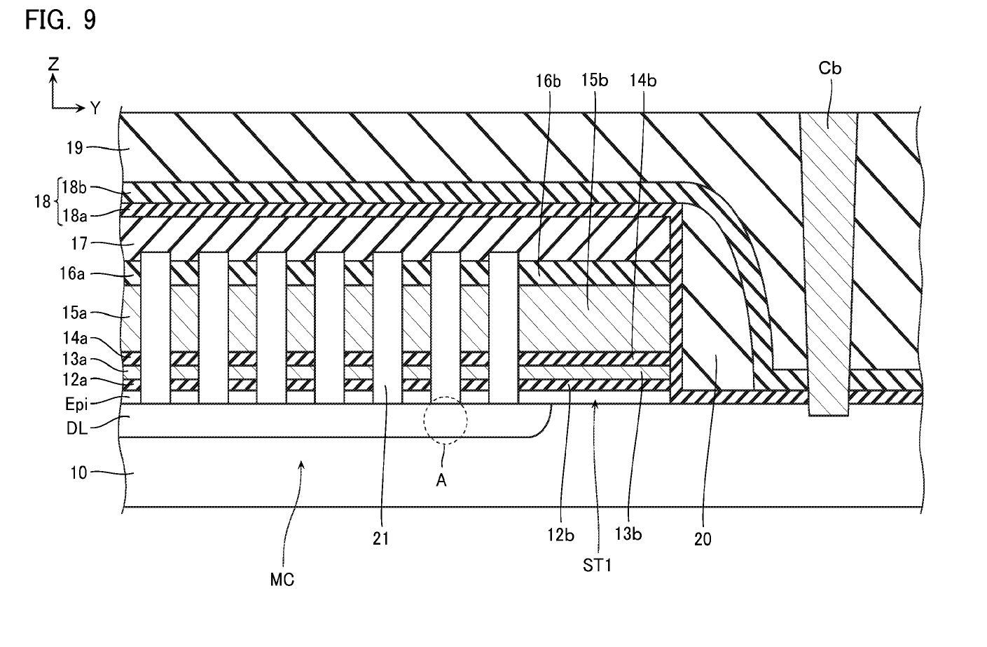

FIG. 9 is a cross-sectional view showing part of the memory string of the nonvolatile semiconductor memory device according to the first embodiment, and corresponds to a cross-sectional view taken along the Y direction and observing from the X direction in FIG. 2.

In the nonvolatile semiconductor memory device according to the present embodiment, a plurality of the memory cells MC, each nonvolatilely accumulating a charge, are disposed along the Y direction on a substrate 10. The Y direction is along the surface of the substrate 10. Moreover, the drain side select transistor ST1 is disposed adjacently to the memory cell MC.

Note that the plurality of memory cells MC and the select transistor ST1 in the present embodiment have similar structures, hence the description below will focus on the memory cell MC. Moreover, the source side select transistor ST2 not illustrated in FIG. 9 also has a similar structure to the drain side select transistor ST1. Therefore, the description below will focus on a drain side structure, and description of a source side structure will be omitted.

As shown in FIG. 9, the plurality of memory cells MC each comprise: a gate insulating film 12a (tunnel insulating film) disposed on a channel region of the substrate 10 and configured from a silicon oxide layer, for example; and a floating gate electrode 13a configured from polysilicon, for example, and disposed on the gate insulating film 12a. A film thickness of the gate insulating film 12a may be set to about 6 nm, for example. A film thickness of the floating gate electrode 13a may be set to about 5 nm, for example. Moreover, in the present embodiment exemplified in FIG. 9, the floating gate electrode 13a has a single-layer structure, but a stacked structure combining a plurality of materials may also be adopted instead of this. In the case of adopting a stacked structure, it is also possible for a metal layer to be adopted as one of elements configuring the stacked structure.

The drain side select transistor ST1 is disposed adjacently to the memory cell MC positioned at a drain side end of the memory string. The drain side select transistor ST1, similarly to the plurality of memory cells MC configuring the memory string, has a structure in which an epitaxial layer Epi, an insulating film 12b, a conductive layer 13b, an insulating layer 14b, a conductive layer 15b, and a cap layer 16b are stacked on the substrate 10.

Note that although not illustrated in FIG. 9, a charge accumulation film may also be disposed on the floating gate electrode 13a. The charge accumulation film has a function of accumulating a charge injected into the floating gate electrode 13a via the gate insulating film 12a by a write operation, and is formed by, for example, silicon nitride (SiN). A film thickness of the charge accumulation film may be set to about 2 nm, for example. Presence of the charge accumulation film makes it possible for an aspect ratio of the floating gate electrode 13a to be reduced.

A block insulating film 14a configured from silicon oxide, for example, is disposed above the floating gate electrode 13a (on the charge accumulation film when a charge accumulation film is formed).

Note that the block insulating film 14a has a single-layer structure in the illustrated example, but is not limited to this, and the block insulating film 14a may also be configured as a stacked structure formed by a plurality of materials. In the case of being configured as a stacked structure, it is possible to adopt a configuration in which, for example, a first layer configured from hafnium oxide (HfOx), a second layer configured from silicon oxide (SiO₂), and a third layer configured from hafnium oxide (HfOx), are stacked. In this case, thicknesses of these layers may each be set to about 5 nm, for example.

Moreover, also employable as materials of the gate insulating film 12a (tunnel insulating film) and the block insulating film 14a, besides silicon oxide (SiOx), are, for example, Al2O3, Y2O3, La2O3 Gd2O3, Ce2O3, CeO2, Ta2O5, HfO2, ZrO2, TiO2, HfSiO, HfAlO, ZrSiO, ZrAlO, AlSiO, and so on.

Moreover, the block insulating film 14a has the following disposed thereon, namely: a conductive layer 15a which is an electrode functioning as a control gate; and a cap layer 16a disposed on an upper portion of the conductive layer 15a.

The conductive layer 15a may be formed by, for example, tungsten (W), tungsten nitride (WN), tungsten silicide (WSix), tantalum (Ta), tantalum nitride (TaN), tantalum silicide (TaSix), palladium silicide (PdSix), erbium silicide (ErSix), yttrium silicide (YSix), platinum silicide (PtSix), hafnium silicide (HfSix), nickel silicide (NiSix), cobalt silicide (CoSix), titanium silicide (TiSix), vanadium silicide (VSix), chromium silicide (CrSix), manganese silicide (MnSix), iron silicide (FeSix), ruthenium (Ru), molybdenum (Mo), titanium (Ti), titanium nitride (TiN), vanadium (V), chromium (Cr), manganese (Mn), iron (Fe), cobalt (Co), nickel (Ni), gold (Au), silver (Ag), or copper (Cu), or by a compound of these, but may also be formed by polysilicon to which an impurity has been added.

The cap layer 16a is configured from, for example, silicon oxide or silicon nitride. This cap layer plays a role of suppressing the conductive layer 15a getting shaved during etching in a later step.

Moreover, the diffusion layer DL implanted with an impurity is disposed continuously along the Y direction in a region straddling the plurality of memory cells MC and the select transistor ST1, of a substrate 10 surface. The diffusion layer DL is formed also in a region straddling the unillustrated source side select transistor ST2. In other words, the plurality of memory cells MC disposed along the Y direction are connected in series by this diffusion layer DL and form the memory string. Moreover, the select transistors ST1 and ST2 are connected in series by this diffusion layer DL to the two ends of the memory string. Moreover, the diffusion layer DL is a P type diffusion layer implanted with a P type impurity such as boron (B), for example.

An inter-layer insulating layer 17 is disposed so as to cover the memory cell MC and the select transistor ST1 and such that a gap 21 is formed between the memory cells MC and between the memory cell MC positioned most at an end and the select transistor ST1. In order to form the gap 21, the inter-layer insulating layer 17 in the present embodiment is formed by the likes of a plasma CVD method using a material having low implanting characteristics such as silane (SiH₄), for example. Note that in order to prevent the gap 21 from being present, the inter-layer insulating layer 17 may be configured present between the memory cells MC and between the memory cell MC positioned most at an end and the select transistor ST1.

Disposed on an upper surface of the inter-layer insulating layer 17 is a barrier layer 18 which is configured from two layers of barrier materials 18a and 18b, for example, and which is for causing the barrier layer 18 to function as an etching stopper material during subsequent contact formation. The barrier layer 18 is configured using, for example, a nitride layer of the likes of silicon nitride whose etching rate differs from that of the inter-layer insulating layer 17. The two layers of barrier material 18a and 18b are disposed contacting each other at an upper portion of the memory cell MC and the select transistor ST1, but at a side portion of the select transistor ST1, are disposed having interposed between them an inter-layer insulating layer 20 configured from the likes of silicon oxide in order to further suppress impurity penetration from the peripheral region.

Further disposed on an upper surface of the barrier layer 18 is an inter-layer insulating layer 19 configured from the likes of silicon oxide.

The bit line contact Cb for electrically connecting the bit line and the substrate 10 is disposed in a periphery of a memory cell array region where the memory cell MC and the select transistor ST1 are disposed. The bit line contact Cb extends in a column shape in a perpendicular direction of the substrate 10, for example, and is configured from a metal such as tungsten.

Moreover, in the present embodiment, the memory cell MC includes the epitaxial silicon layer Epi configured from epitaxial silicon, and the epitaxial silicon layer Epi is disposed on the diffusion layer DL. In the present embodiment, the epitaxial silicon layer Epi is divided between each of the memory cells MC configuring the memory string.

Now, the memory cell MC nonvolatilely stores data by a charge accumulation state of the floating gate electrode 13a. Specifically, for example, a state of high threshold voltage where electrons have been injected into the floating gate electrode from a channel is assumed to be “0” data, for example, and a state of low threshold voltage where electrons of the floating gate electrode have been emitted to the channel is assumed to be “1” data, whereby binary data storage is performed. In addition, a multi-value storage system such as four-value storage is also performed by further subdividing threshold distribution control.

Variation of threshold value of the memory cell is greatly influenced by the number of electrons present in the floating gate electrode and the number of electrons trapped by repeating write erase, and by ease of transmission of a cell current due to impurity variation of the diffusion layer. These variations are expressed as variation of a so-called S factor, that is, a rate of change of a Schottky barrier with respect to work function of a metal configuring the electrode in a current-voltage characteristics curve (IV curve) of the cell.

Along with miniaturization of memory cells that has been required in recent years, sensitivity to variation of activation or implantation amount of these impurities has increased to become a cause of variation of cell characteristics.

In order to deal with such a problem, in the present embodiment, the diffusion layer DL implanted with a P type impurity is formed so as to straddle the entire memory string, and a fringe electric field generated between the memory cells MC utilizing this diffusion layer DL is employed to control On/Off of the memory cell MC.

A voltage applied to the memory cell MC causes the diffusion layer DL directly below the word line (control gate electrode 15a) to invert, whereby a channel is formed. In addition, by utilizing the fringe electric field in the present embodiment, the diffusion layer DL inverts to form a channel also in a region between the memory cells MC where the word line (control gate electrode 15a) is not formed (region shown by reference symbol A in FIG. 9, for example).

Moreover, in the present embodiment, the epitaxial silicon layer Epi is further disposed between the memory cell MC and the diffusion layer DL. This epitaxial silicon layer Epi is inverted to control On/Off of the memory cell MC. As a result of utilizing the epitaxial layer Epi as a channel in this way, tolerance to variation in cell characteristics caused by variation in dimensions of the word line and variation in the gap between the memory cells MC improves. Furthermore, it becomes possible to suppress variation in cell characteristics caused by variation in an amount of impurity contained by the diffusion layer DL directly below the memory cell MC.

Specifically, impurity concentration of the epitaxial silicon layer Epi is constant, hence a gate voltage enabling an inversion layer to be formed is also more constant between the memory cells MC than in the diffusion layer DL that has variation in impurity concentration. Therefore, it is more difficult for variation to occur in threshold voltage of the memory cell MC and a voltage when rendering the memory cell MC conductive is more constant between the memory cells, compared to a memory cell having only the diffusion layer DL that has variation in impurity concentration.

### Method of Manufacturing Nonvolatile Semiconductor Memory Device According to First Embodiment

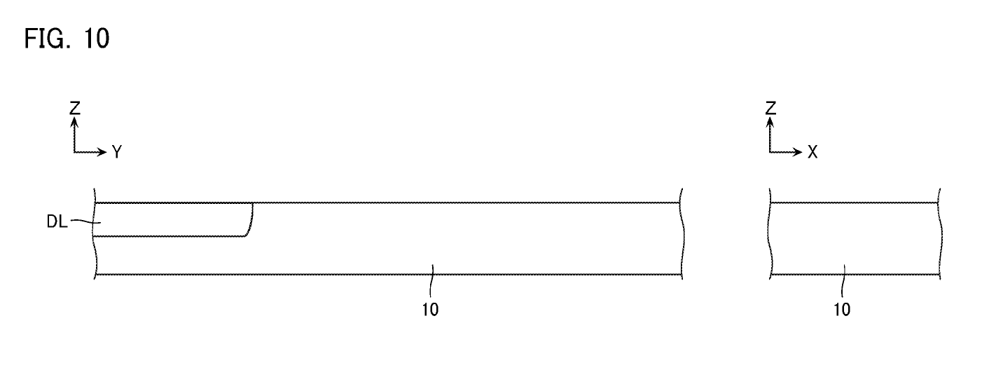

Next, a method of manufacturing the nonvolatile semiconductor memory device according to the first embodiment will be described with reference to FIGS. 10 to 20. In the drawings showing manufacturing steps below, a view (left side) in which a cross-section along the Y direction is seen from the X direction and a view (right side) in which a cross-section along the X direction is seen from the Y direction, of the plurality of memory cells MC disposed to form the memory string, are illustrated side by side.

Note that in the present embodiment, the memory cell MC and the select transistor ST1 are formed simultaneously, and, as mentioned above, have an identical stacked structure. Therefore, for simplification of explanation, description will be made below with reference to reference symbols assigned to the memory cell MC.

As shown in FIG. 10, a P type impurity such as boron (B) is implanted in a surface on the substrate 10 configured from silicon, and the P type diffusion layer DL is formed. During this diffusion layer DL formation, in the present embodiment, the diffusion layer DL between the memory cells MC disposed in the X direction is removed to divide the diffusion layer DL in the X direction in a later-mentioned element isolation step. However, it is possible to configure so as to utilize the likes of a mask material, for example, during implantation of the impurity and form the diffusion layer DL in a state of being divided in the X direction from the start.

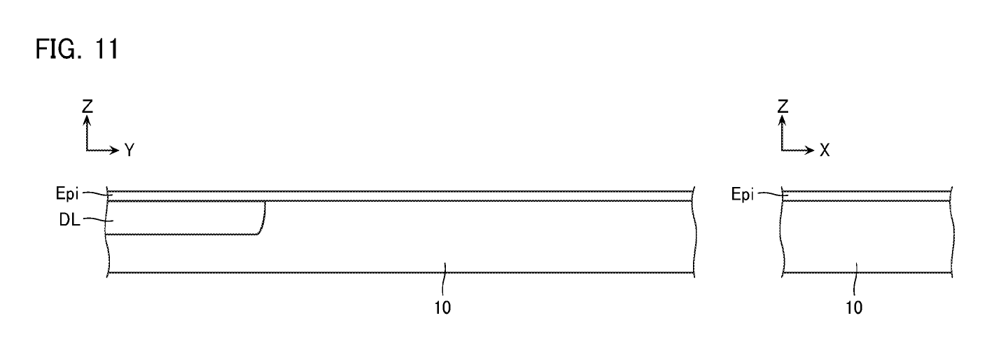

As shown in FIG. 11, a homoepitaxy method adopting silicon configuring the substrate 10 as a material, is employed to grow epitaxial silicon and form the epitaxial silicon layer Epi on the surface of the substrate 10. A thickness of this epitaxial silicon layer Epi is about 5 nm, for example. A region where the epitaxial silicon layer Epi is formed, is formed under the same conditions as the diffusion layer DL described above. In other words, when the diffusion layer DL is formed without being divided in the X direction, the epitaxial silicon layer Epi is also formed on an entire surface of the substrate 10 and is divided in the X direction in the subsequent element isolation step. When the mask and so on is employed to form the diffusion layer DL on the substrate 10 in a state of being divided in the X direction, the epitaxial silicon layer Epi is also formed on the substrate 10 in a state of being divided in the X direction.

Moreover, in the above-described, the epitaxial silicon layer Epi is formed after formation of the diffusion layer DL, but the diffusion layer DL may be formed after formation of the epitaxial silicon layer Epi. In that case, when performing impurity implantation for forming the diffusion layer DL, an implantation point of the impurity is made deeper than the epitaxial silicon layer Epi, and mixing of the impurity in the epitaxial silicon layer Epi is suppressed. That is, impurity concentration in the epitaxial silicon layer Epi is preferably lower than impurity concentration of the diffusion layer DL. Specifically, it is preferable that an impurity concentration of whatever point of the epitaxial silicon layer Epi is taken, a point having an impurity concentration higher than that impurity concentration is present in the diffusion layer DL.

Thus, the epitaxial silicon configuring the epitaxial silicon layer Epi need only have an impurity concentration lower than that of the diffusion layer DL, and may be in a state of being doped with an impurity or in a non-doped state of not being doped.

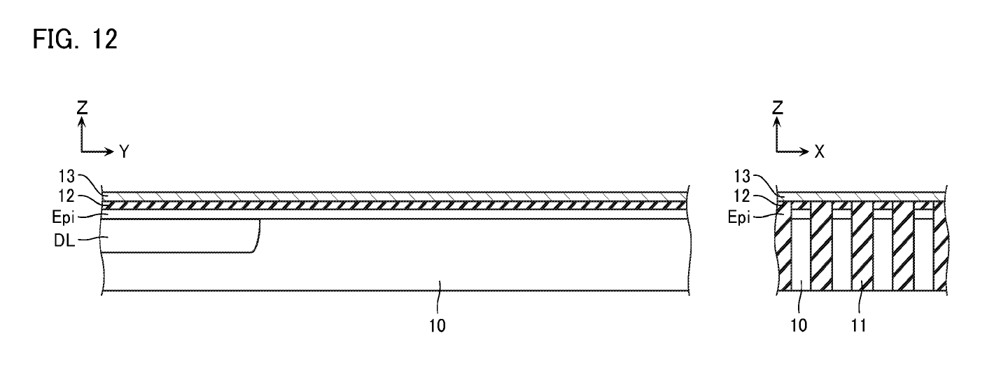

As shown in FIG. 12, an insulating layer 12 configured from silicon oxide is formed on an upper surface of the epitaxial silicon layer Epi. A conductive layer 13 configured from polysilicon is formed on an upper surface of the insulating layer 12. Then, an STI (Shallow Trench Insulator) is formed along the Y direction in the surface of the substrate 10, this STI is filled with the element isolation insulating film 11 configured from silicon oxide, and the active area AA is formed. As a result of this step, when the diffusion layer DL and the epitaxial silicon layer Epi are formed on an entire region of the surface of the substrate 10 in the steps explained by FIGS. 10 and 11, the diffusion layer DL and the epitaxial silicon layer Epi are divided in the X direction so as to extend in the Y direction and be arranged in parallel in the X direction.

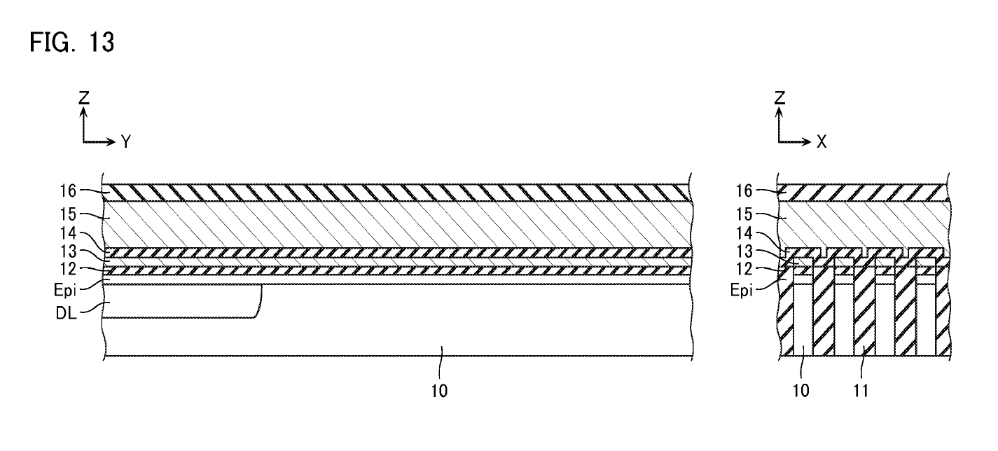

As shown in FIG. 13, an insulating layer 14 configured from silicon oxide is formed on the conductive layer 13.

A conductive layer 15 configured from tungsten is formed on the insulating layer 14. A cap layer 16 configured from silicon nitride is formed on an upper surface of the conductive layer 15.

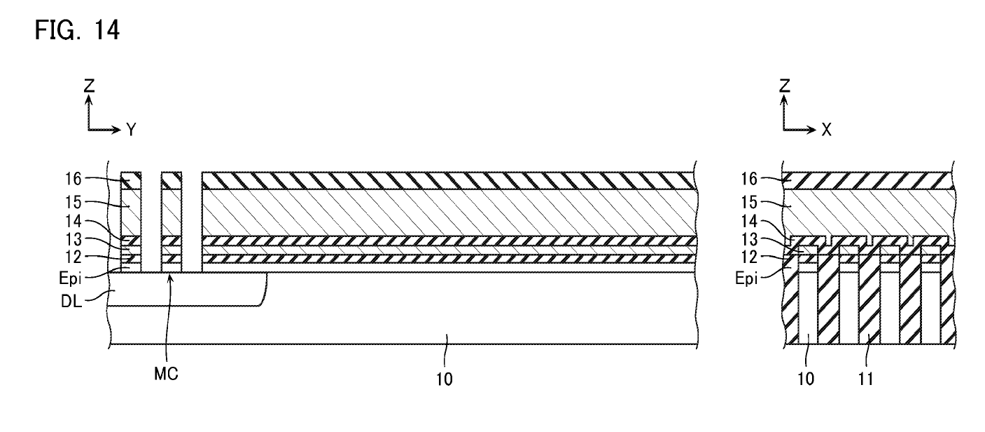

As shown in FIG. 14, an unillustrated mask is formed on an upper surface of the cap layer 16 to perform etching along the X direction and form a portion that will be the memory cell MC. This step results in a plurality of the memory cells MC being formed along the X direction and the Y direction intersecting this X direction. The X direction and the Y direction are along the surface of the substrate 10. Moreover, in the present embodiment, the epitaxial silicon layer Epi formed on the substrate 10 surface between the memory cells MC formed along the Y direction by this step, is removed.

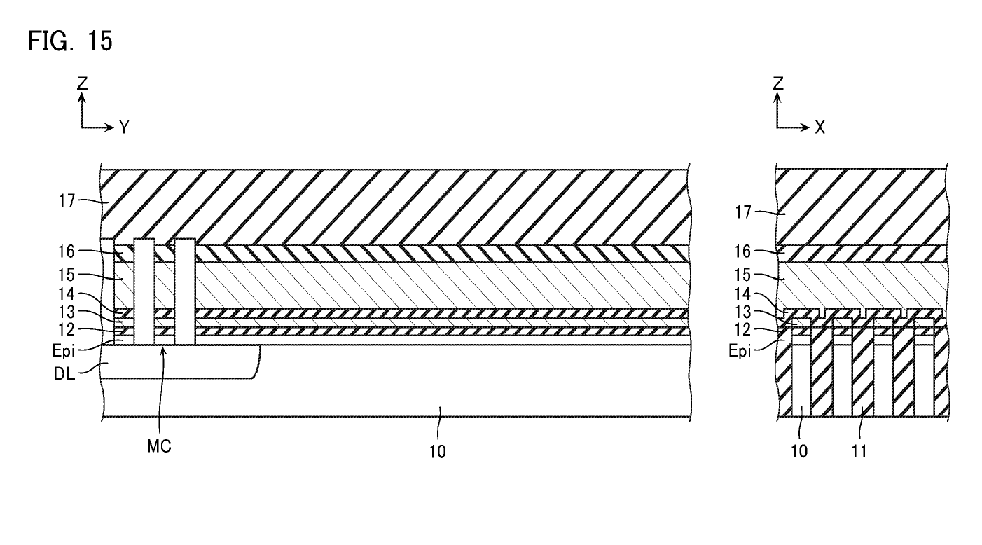

As shown in FIG. 15, the inter-layer insulating layer 17 is formed in a layer above the cap layer 16, by the likes of a plasma CVD method using silane, for example. A layer formed by a plasma CVD method using silane has low implanting characteristics, hence the gap 21 is formed between the memory cells MC and between the memory cell MC positioned most at an end and the select transistor ST1.

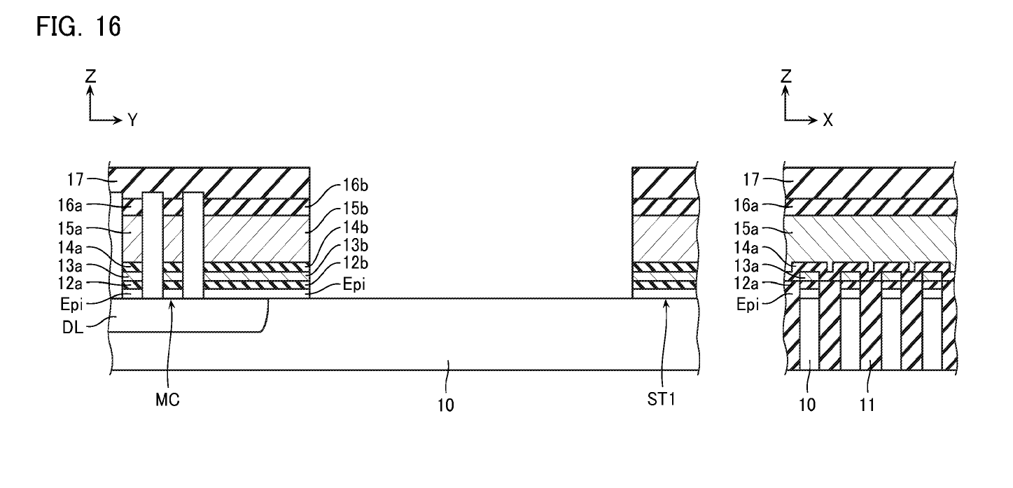

As shown in FIG. 16, etching is performed in a state where a portion that will be the memory cell MC and the select transistor ST1 has been coated with an unillustrated mask material, and a structure between adjacent drain side select transistors ST1 is removed.

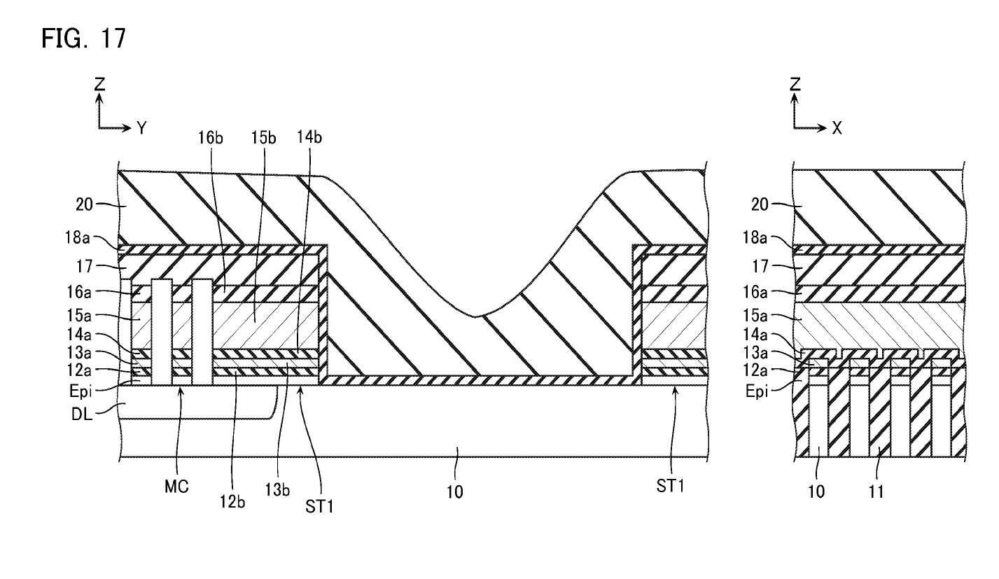

As shown in FIG. 17, a cover material 18a configured from the likes of silicon nitride is deposited so as to cover an upper surface of the inter-layer insulating layer 17 and on the substrate 10 between the adjacent drain side select transistors ST1 explained by FIG. 16. Then, an inter-layer insulating layer 20 configured from silicon oxide is deposited so as to cover an upper surface of the cover material 18a.

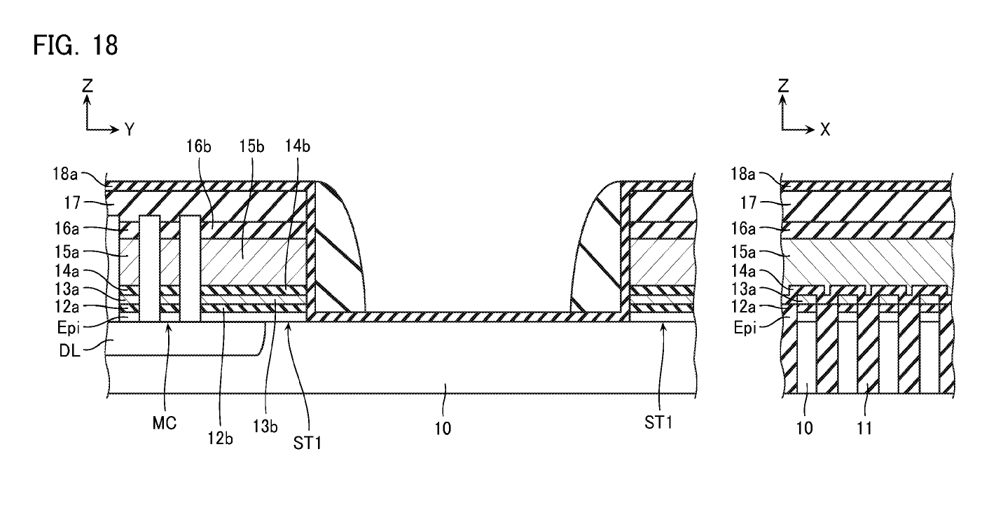

As shown in FIG. 18, perpendicular anisotropic etching such as RIE is implemented, and the inter-layer insulating layer 20 deposited on the upper surface of the cover material 18a and in a central portion between the select transistors ST1 is removed. Thus, the inter-layer insulating layer 20 remains only on a side of a side surface of the select transistor ST1.

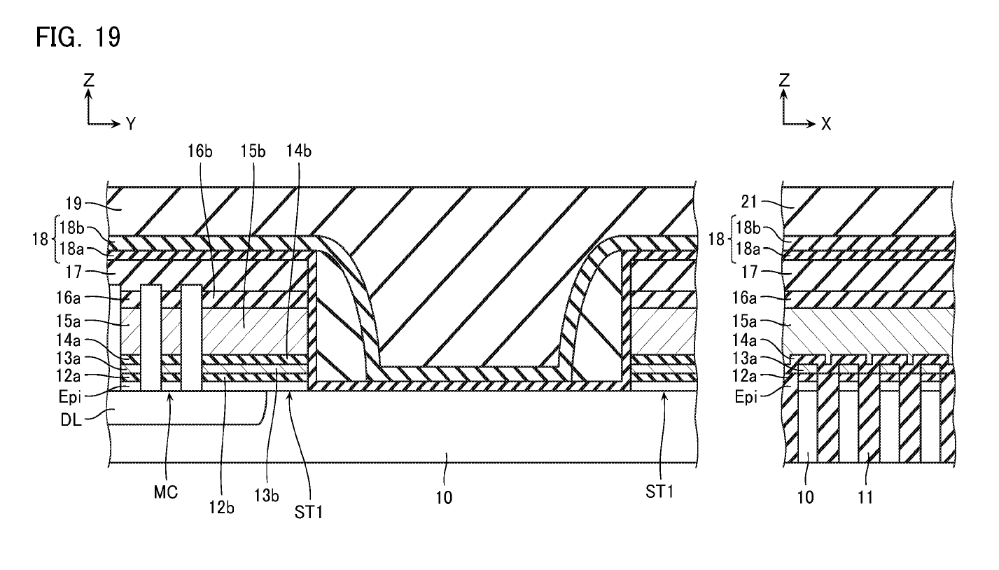

As shown in FIG. 19, a cover material 18b configured from silicon nitride is deposited so as to cover the cover material 18a and the inter-layer insulating layer 20, and the inter-layer insulating layer 19 configured from silicon oxide is deposited so as to cover an upper surface of the cover material 18b.

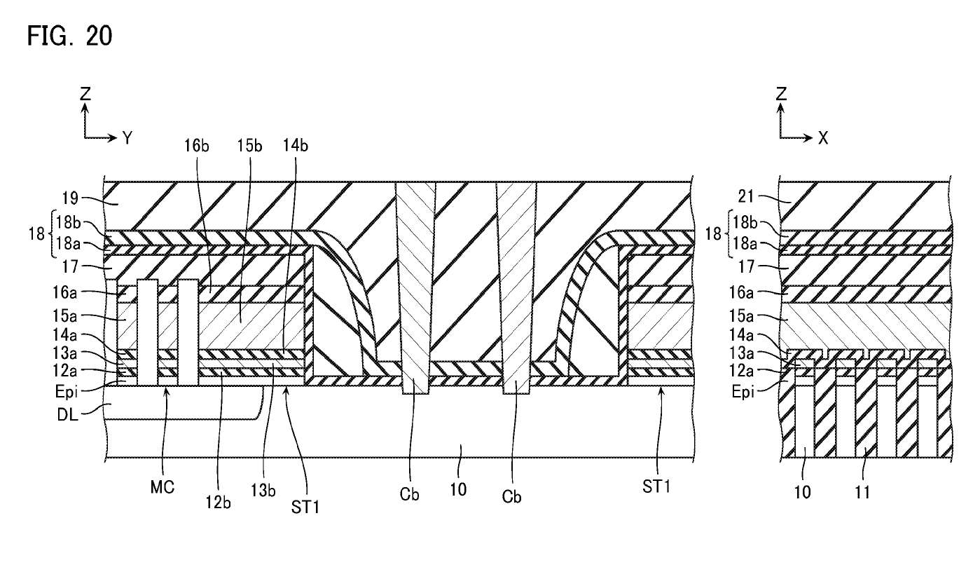

As shown in FIG. 20, a hole is formed by etching between the select transistors ST1, and the bit line contact Cb is formed by implanting tungsten in said hole. As a result of the above steps, the configuration shown in FIG. 9 is obtained.

### Second Embodiment

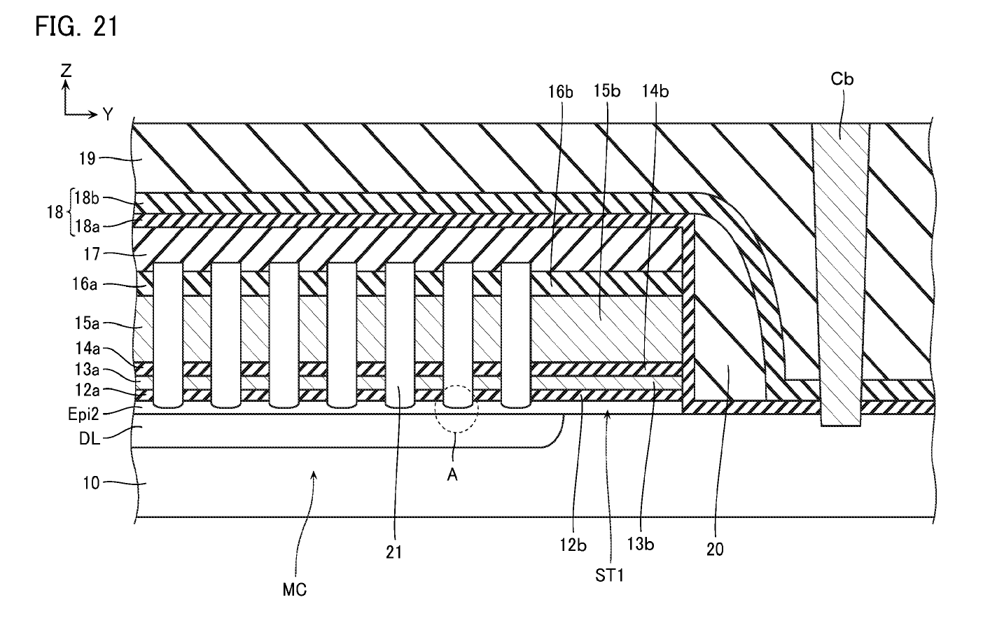

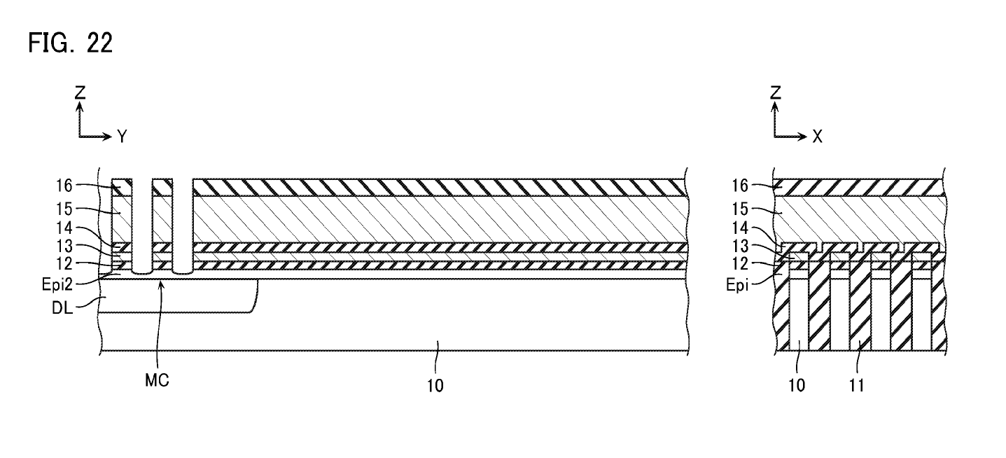

A nonvolatile semiconductor memory device according to a second embodiment will be described with reference to FIGS. 21 and 22.

### Configuration of Nonvolatile Semiconductor Memory Device According to Second Embodiment

The nonvolatile semiconductor memory device according to the second embodiment has a configuration largely identical to that of the nonvolatile semiconductor memory device according to the first embodiment, identical elements are assigned with identical reference symbols to those assigned in the first embodiment, and descriptions thereof will be omitted.

The nonvolatile semiconductor memory device according to the second embodiment has a configuration of its epitaxial silicon layer which differs from that of the nonvolatile semiconductor memory device according to the first embodiment.

An epitaxial silicon layer Epi2 in the present embodiment is not only included in the memory cell MC and disposed on the diffusion layer DL, but also disposed between the plurality of memory cells MC disposed along the Y direction to configure the memory string and between the memory cell MC positioned most at an end and the drain side select transistor ST1 and unillustrated source side select transistor ST2. In other words, the epitaxial silicon layer Epi2 is disposed continuously between the drain side select transistor ST1 and the source side select transistor ST2 positioned at the two ends of the memory string.

In addition, a thickness in a Z direction of the epitaxial silicon layer Epi2 included in the memory cell MC is configured greater than a thickness in the Z direction of the epitaxial silicon layer Epi2 formed between the memory cells MC (portion indicated by the reference symbol A in FIG. 21).

Such a configuration results in the epitaxial silicon layer Epi2 present between the memory cells MC also being inverted by the fringe electric field generated between the memory cells MC, and a channel being formed. This makes it possible for variation in cell characteristics caused by variation in impurity concentration of the diffusion layer DL to be further suppressed.

### Method of Manufacturing Nonvolatile Semiconductor Memory Device According to Second Embodiment

A method of manufacturing the nonvolatile semiconductor memory device according to this second embodiment is first similar to the first embodiment up to the method of manufacturing the nonvolatile semiconductor memory device according to the first embodiment explained by FIGS. 10 to 13.

As shown in FIG. 22, in the second embodiment, in the step of memory cell formation after the step explained by FIG. 13 (step shown by FIG. 14 in the first embodiment), it is only required to configure to adjust a depth of etching such that part of the epitaxial silicon layer Epi2 between the memory cells MC remains.

In other words, the epitaxial silicon layer Epi2 between the memory cells MC has a part thereof etched. As a result, the thickness in the Z direction of the epitaxial silicon layer Epi2 included in the memory cell MC is configured greater than the thickness in the Z direction of the epitaxial silicon layer Epi2 formed between the memory cells MC (portion indicated by the reference symbol A in FIG. 21).

Subsequent steps are identical to those of the method of manufacturing the nonvolatile semiconductor memory device according to the first embodiment explained by FIGS. 15 to 20.

Note that the second embodiment described the case where the epitaxial silicon layer Epi2 is present also between the memory cells MC, and the thickness in the Z direction of the epitaxial silicon layer Epi2 included in the memory cell MC is configured greater than the thickness in the Z direction of the epitaxial silicon layer Epi2 formed between the memory cells MC. However, it is also possible to adjust etching to form the epitaxial silicon layer such that the thickness in the Z direction of the epitaxial silicon layer Epi2 included in the memory cell MC is equal to the thickness in the Z direction of the epitaxial silicon layer Epi2 formed between the memory cells MC.

### COMPARATIVE EXAMPLES

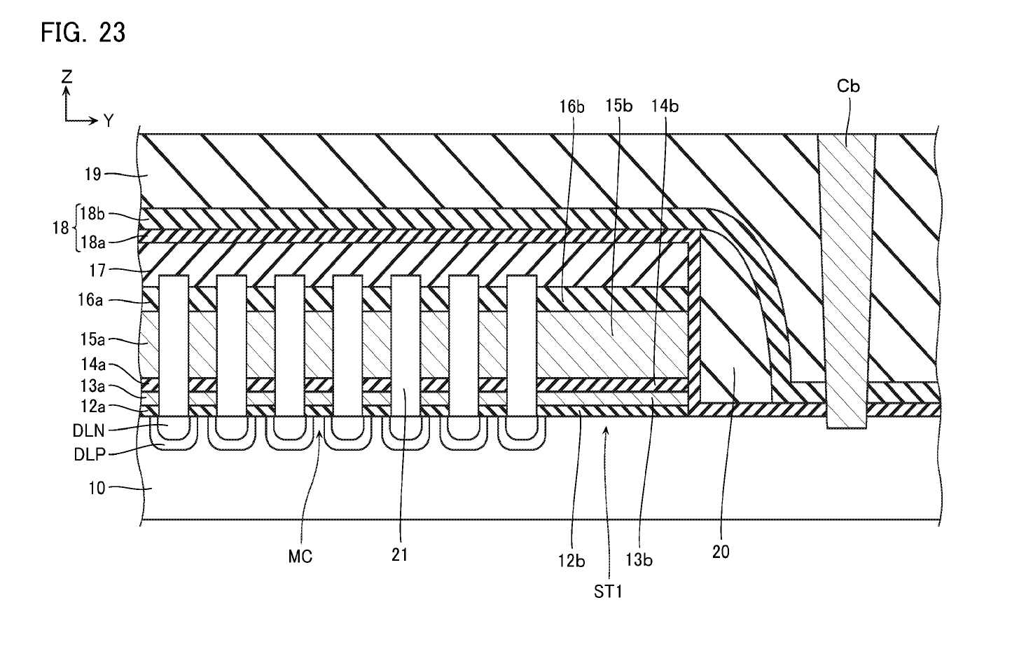

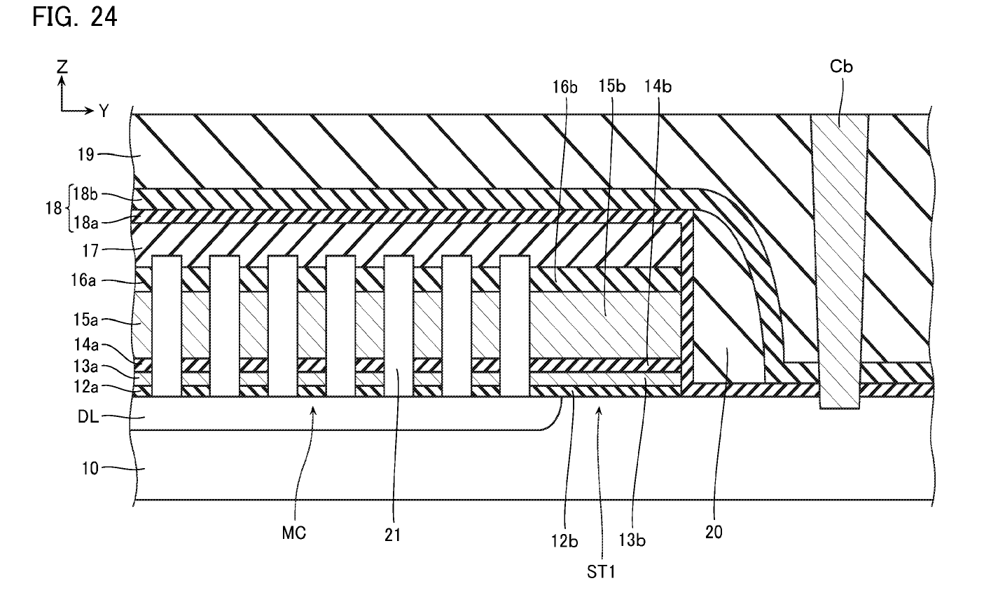

Finally, nonvolatile semiconductor memory devices according to comparative examples will be described using FIGS. 23 and 24.

In both of the nonvolatile semiconductor memory devices according to the comparative examples, the epitaxial silicon layer on the substrate is not formed. Moreover, the nonvolatile semiconductor memory device according to the comparative example shown in FIG. 23 has a configuration of its diffusion layer which differs from those of the nonvolatile semiconductor memory devices according to the first and second embodiments.

The nonvolatile semiconductor memory device according to the comparative example shown in FIG. 23 is of a so-called N type cell.

This N type cell includes the following on the substrate 10, namely: an N type diffusion layer DLN implanted with an N type impurity such as arsenic (As) or phosphorus (P), for example; and a P type diffusion layer DLP implanted with a P type impurity such as boron (B) for adjusting a threshold value of the channel. In other words, this N type cell has an impurity of the same kind as the channel region restrictively implanted only at tips of the source and drain, and is also referred to as a Halo structure.

In a memory cell having a Halo type structure, along with miniaturization of memory cells that has been required in recent years, the number of electrons stored in the memory cell MC has dramatically decreased, and as a result, an extent of influence exerted on the threshold value when one electron has escaped from the memory cell MC has increased. In addition, sensitivity to variation in activation or implantation amount of these impurities has increased to become a cause of variation in cell characteristics.

On the other hand, the nonvolatile semiconductor memory device according to another comparative example shown in FIG. 24 has also been proposed as a contrivance to counter such a problem.

The nonvolatile semiconductor memory device shown in FIG. 24 has a fringe cell structure in which the P type diffusion layer DL is provided continuously corresponding to the memory string. In the fringe cell structure, implantation to the substrate 10 of the P type impurity for threshold value adjustment is implemented before forming the word line.

As a result of such a structure, a voltage applied to the gate electrode not only causes a channel to be formed directly below the gate electrode but causes a channel to be formed also in a portion between the memory cells, and there is an improvement in variation in cell characteristics due to word line dimension and gap variations, by setting to On. However, On/Off switching characteristics nevertheless change due to an impurity amount in the diffusion layer directly below the gate electrode, hence complete suppression of variation in cell characteristics was not achieved.

### [Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed Is:

1. A nonvolatile semiconductor memory device, comprising:
a silicon substrate;
a plurality of memory cells disposed along at least a first direction, on the substrate, the plurality of the memory cells nonvolatilely accumulating a charge; and
a diffusion layer disposed continuously in a surface of the substrate of a region straddling the plurality of memory cells disposed along the first direction; wherein
the memory cell includes an epitaxial silicon layer disposed on the diffusion layer.

2. The nonvolatile semiconductor memory device according to claim 1, further comprising:
a plurality of the memory cells disposed along a second direction, the second direction intersecting the first direction; and
an element isolation insulating film disposed between the plurality of memory cells disposed along the second direction.

3. The nonvolatile semiconductor memory device according to claim 1, wherein
the plurality of memory cells disposed along the first direction configure a memory string whose one end is connected to a source side select transistor and whose other end is connected to a drain side select transistor, and
the epitaxial silicon layer is disposed continuously between the source side select transistor and the drain side select transistor connected to the two ends of the memory string, so as to be included in the memory cell and disposed between the plurality of memory cells.

4. The nonvolatile semiconductor memory device according to claim 1, wherein
the plurality of memory cells disposed along the first direction configure a memory string whose one end is connected to a source side select transistor and whose other end is connected to a drain side select transistor, and
the epitaxial silicon layer is divided between each of the memory cells configuring the memory string.

5. The nonvolatile semiconductor memory device according to claim 3, wherein
a thickness in a third direction orthogonal to the first direction of the substrate of the epitaxial silicon layer included in the memory cell is greater than a thickness in the third direction of the epitaxial silicon layer disposed between the plurality of memory cells.

6. The nonvolatile semiconductor memory device according to claim 1, wherein
an impurity concentration in the diffusion layer is higher than an impurity concentration in the epitaxial silicon layer.

7. The nonvolatile semiconductor memory device according to claim 1, wherein
the diffusion layer is a P type diffusion layer.

8. A method of manufacturing a nonvolatile semiconductor memory device, comprising:
implanting an impurity in a silicon substrate surface to form a diffusion layer;
forming an epitaxial silicon layer in a region where the diffusion layer is formed on the substrate; and
forming a plurality of memory cells on the epitaxial silicon layer, the plurality of memory cells being formed along at least a first direction on the substrate, the first direction being along a surface of the substrate, and the plurality of the memory cells nonvolatilely accumulating a charge.

9. The method of manufacturing a nonvolatile semiconductor memory device according to claim 8, comprising:
further forming a plurality of memory cells along a second direction intersecting the first direction, on the substrate; and
forming an element isolation insulating layer between the plurality of memory cells disposed along the second direction, thereby dividing the diffusion layer and the epitaxial silicon layer in the second direction.

10. The method of manufacturing a nonvolatile semiconductor memory device according to claim 8, comprising:
connecting in series the plurality of memory cells disposed along the first direction and thereby configuring a memory string;
forming a source side select transistor adjacently to the memory cell positioned at one end of the memory string, and forming a drain side select transistor adjacently to the memory cell positioned at the other end of the memory string; and
forming the epitaxial silicon layer so as to be disposed continuously between the source side select transistor and the drain side select transistor connected to the two ends of the memory string, so as to be included in the memory cell and disposed between the plurality of memory cells.

11. The method of manufacturing a nonvolatile semiconductor memory device according to claim 8, comprising:
connecting in series the plurality of memory cells disposed along the first direction and thereby configuring a memory string;
forming a source side select transistor adjacently to the memory cell positioned at one end of the memory string, and forming a drain side select transistor adjacently to the memory cell positioned at the other end of the memory string; and
dividing the epitaxial silicon layer between each of the memory cells configuring the memory string.

12. The method of manufacturing a nonvolatile semiconductor memory device according to claim 10, comprising:
etching part of a surface of the epitaxial silicon layer between the plurality of memory cells formed along the first direction; and
making a thickness in a third direction orthogonal to the first direction of the substrate of the epitaxial silicon layer disposed between the plurality of memory cells less than a thickness in the third direction of the epitaxial silicon layer included in the memory cell.

13. The method of manufacturing a nonvolatile semiconductor memory device according to claim 8, wherein
an impurity concentration in the diffusion layer is higher than an impurity concentration in the epitaxial silicon layer.

14. The method of manufacturing a nonvolatile semiconductor memory device according to claim 8, wherein
an impurity implanted in the substrate surface is P type.

15. The method of manufacturing a nonvolatile semiconductor memory device according to claim 8, wherein
formation of the diffusion layer is performed after formation of the epitaxial silicon layer, and
implantation of the impurity is performed on a region positioned more downwardly than a lower surface of the epitaxial silicon layer of the silicon substrate so as to prevent the impurity from being implanted in the epitaxial silicon layer.
